(19) United States
(12) Patent Application Publication
(10) Pub. No.: US 2026/0059657 A1
(43) Pub. Date: Feb. 26, 2026

(54) PRINTED CIRCUIT BOARD

(71) Applicant: SAMSUNG ELECTRO-MECHANICS CO., LTD., Suwon-si (KR)

(72) Inventors: Sang Hyeok KIM, Suwon-si (KR); In Gun KIM, Suwon-si (KR); Ho Seung JANG, Suwon-si (KR); Mi Geum KIM, Suwon-si (KR); Sangik CHO, Suwon-si (KR); Jong Eun PARK, Suwon-si (KR)

(73) Assignee: SAMSUNG ELECTRO-MECHANICS CO., LTD., Suwon-si (KR)

(21) Appl. No.: 19/176,623

(22) Filed: Apr. 11, 2025

(30) Foreign Application Priority Data
Aug. 21, 2024 (KR) 10-2024-0112000

(51) Int. Cl. H05K 1/03; H05K 1/11

(52) U.S. Cl. CPC H05K 1/0306; H05K 1/115; H05K 2201/0158

(57) ABSTRACT

A printed circuit board including: a plurality of insulating layers; a plurality of wiring layers; a plurality of vias; a glass substrate having an upper surface and a lower surface, a first side surface and a second side surface and a third side surface and a fourth side surface, and at least partially disposed between the plurality of insulating layers; and a protection material covering the first to fourth side surfaces of the glass substrate, and each of the upper surface and the lower surface of the glass substrate may have a peripheral portion connected to the first to fourth side surfaces and a central portion surrounded by the peripheral portion, and the protection material may be spaced apart from central portions of the upper surface and the lower surface of the glass substrate, respectively.

### CROSS-REFERENCE TO RELATED APPLICATION(S)

This application claims benefit of priority to Korean Patent Application No. 10-2024-0112000 filed on Aug. 21, 2024, in the Korean Intellectual Property Office, the disclosure of which is incorporated herein by reference in its entirety.

### TECHNICAL FIELD

The present disclosure relates to a printed circuit board.

Efforts to improve the performance of electronic products are moving beyond semiconductors to packaging, and products utilizing glass substrates are attracting attention as next-generation technologies. Glass substrates may have advantages over organic substrates formed of epoxy materials in terms of heat dissipation, warpage control, large-area expansion, and microcircuit implementation. However, glass substrates may have problems determined by the occurrence and propagation of cracks during processing or transport thereof. In this case, glass particles may enter the product through various paths such as processing equipment or chemicals, leading to product defects. Therefore, it may be necessary to solve the problem of cracks or breakage of glass.

### SUMMARY

An aspect of the present disclosure is to provide a printed circuit board including a glass substrate, thereby effectively preventing cracking or breakage of the glass.

One of the various solutions proposed through the present disclosure is to form dampers having various shapes using a protection material on an edge surface of a glass substrate to protect and absorb external impacts, thereby preventing cracks or breakage of the glass.

For example, a printed circuit board according to an example embodiment may include: a plurality of insulating layers; a plurality of wiring layers respectively disposed on or within the plurality of insulating layers; a plurality of vias, each via among the plurality of vias penetrating through at least one of the plurality of insulating layers, and each via among the plurality of vias connecting to at least one of the plurality of wiring layers; a glass substrate having a first surface and a second surface opposing each other in a first direction, a first side surface and a second side surface opposing each other in a second direction perpendicular to the first direction, and a third side surface and a fourth side surface opposing each other in a third direction perpendicular to the first and second directions, the glass substrate is at least partially disposed between the plurality of insulating layers in the first direction; and a protection material covering the first to fourth side surfaces of the glass substrate, and each of the first surface and the second surface of the glass substrate may have a peripheral portion connected to the first to fourth side surfaces and a central portion surrounded by the peripheral portion, and the protection material may be spaced apart from central portions of the first surface and the second surface of the glass substrate, respectively.

For example, a printed circuit board according to an example embodiment may include: a glass substrate having a first surface and a second surface opposing each other in a first direction, a first side surface and a second side surface opposing each other in a second direction perpendicular to the first direction, and a third side surface and a fourth side surface opposing each other in a third direction perpendicular to the first and second directions; a protection material covering the first to fourth side surfaces of the glass substrate; and a wiring structure disposed on at least one of the first surface and the second surface of the glass substrate, and each of the first surface and the second surface of the glass substrate may have a peripheral portion connected to the first to fourth side surfaces and a central portion surrounded by the peripheral portion, the protection material may further cover at least a portion of the peripheral portion of the first surface of the glass substrate and at least a portion of the peripheral portion of the second surface of the glass substrate, and the protection material may be spaced apart from the central portions of each of the first surface and the second surface of the glass substrate.

One of the various effects of the present disclosure is to provide a printed circuit board including a glass substrate, and capable of effectively preventing cracking or breakage of the glass.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a perspective view schematically illustrating an example of a glass substrate having a protection material formed thereon;

FIGS. 4A to 4C are each an enlarged cross-sectional view schematically illustrating an example of region A of a glass substrate having the protection material of FIG. 3 formed thereon;

FIG. 5 is a process cross-sectional view schematically illustrating various examples of a process of forming a protection material on an edge surface of a glass substrate;

FIG. 6 is a cross-sectional view schematically illustrating an example of a printed circuit board; and

FIG. 7 is a cross-sectional view schematically illustrating another example of a printed circuit board.

### DETAILED DESCRIPTION

Hereinafter, the present disclosure will be described with reference to the accompanying drawings. In the drawings, the shape and size of the elements may be exaggerated or reduced for clearer description.

### Electronic Device

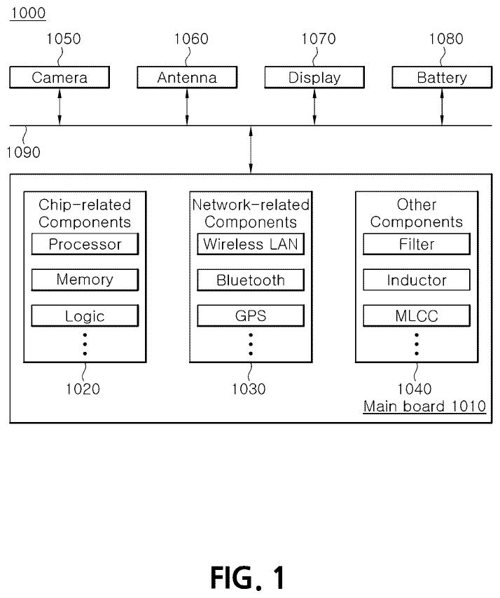

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

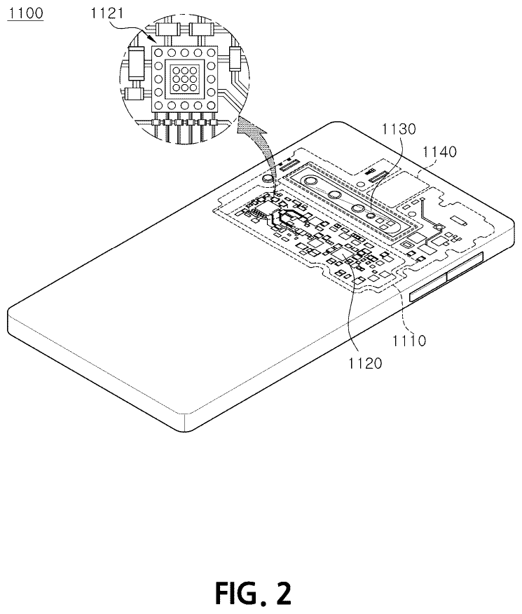

FIG. 2 is a perspective view schematically illustrating an example of an electronic device.

Referring to FIG. 2, an electronic device may be, for example, a smartphone 1100. A mother board 1110 may be accommodated in the smartphone 1100, and various components 1120 may be physically and/or electrically connected to the mother board 1110. Furthermore, other components that may or may not be physically and/or electrically connected to the mother board 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may have the form of a printed circuit board in which an electronic component including an active component and/or a passive component is mounted on a surface. Alternatively, the component package 1121 may have the form of a printed circuit board in which an active component and/or a passive component are embedded. On the other hand, the electronic device is not necessarily limited to the smartphone 1100, and may be other electronic devices as described above.

### Printed Circuit Board

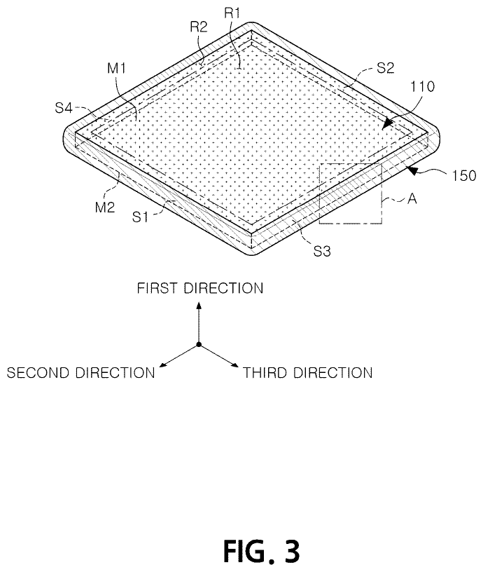

FIG. 3 is a perspective view schematically illustrating an example of a glass substrate having a protection material formed thereon.

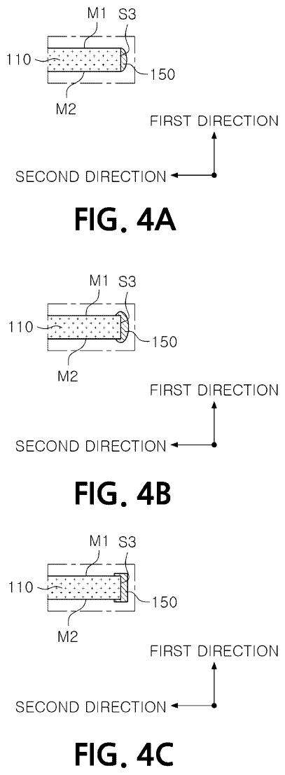

FIGS. 4A to 4C are each an enlarged cross-sectional views schematically illustrating an example of region A of a glass substrate having the protection material of FIG. 3 formed thereon.

Referring to the drawing, a glass substrate 110 may have an upper surface (first surface) M1 and a lower surface (second surface) M2 opposing each other in a first direction, a first side surface S1 and a second side surface S2 opposing each other in a second direction, perpendicular to the first direction, and a third side surface S3 and a fourth side surface S4 opposing each other in a third direction, perpendicular to the first and second directions, respectively. The upper surface M1 of the glass substrate 110 may have a peripheral portion R2 connected to the first to fourth side surfaces S1, S2, S3 and S4 and a central portion R1 surrounded by the peripheral portion R2. Boundaries separating the central portion R1 and the peripheral portion R2 are not particularly limited, and may have any shape as long as the peripheral portion R2 has a predetermined area connected to the first to fourth side surfaces S1, S2, S3 and S4 and surrounding the central portion R1. The lower surface M2 of the glass substrate 110 may also have a peripheral portion connected to the first to fourth side surfaces S1, S2, S3 and S4 and a central portion surrounded by the peripheral portion, and the above-described description may be applied equally thereto.

The glass substrate 110 may include glass, which is an amorphous solid. The glass may include, for example, pure silicon dioxide (about 100% SiO₂), soda lime glass, borosilicate glass, and alumino-silicate glass. However, the present disclosure is not limited thereto, and alternative glass materials, for example, fluorine glass, phosphate glass, chalcogen glass, or the like, may also be used as materials of the glass substrate 110. Additionally, other additives may be further included to form glass having specific physical properties. These additives may include calcium carbonate (e.g., lime) and sodium carbonate (e.g., soda), as well as magnesium, calcium, manganese, aluminum, lead, boron, iron, chromium, potassium, sulfur and antimony, and carbonates and/or oxides of these and other elements. The glass substrate 110 may be distinguished from organic insulating materials including glass fiber (Glass Fiber, Glass Cloth or Glass Fabric), such as Copper Clad Laminate (CCL) or PPG (Prepreg). For example, the glass substrate 110 may include a glass plate.

A protection material 150 may cover the first to fourth side surfaces S1, S2, S3 and S4 of the glass substrate 110, and may be spaced apart from central portions R1 and R3 of the upper surface and the lower surface of the glass substrate 110, respectively. The protection material 150 may have various shapes, sizes, curvatures, and the like. For example, as in FIG. 4A, the protection material 150 may be spaced apart from peripheral portions R2 and R4 of the upper surface and the lower surface of the glass substrate 110, and may protrude in a substantially round shape from each of the first to fourth side surfaces S1, S2, S3 and S4 of the glass substrate 110 based on the second or third direction. In this case, the glass substrate 110 on which the protection material 150 is formed more compactly may be embedded in a printed circuit board. Alternatively, as in FIG. 4B, the protection material 150 may extend to the peripheral portions R2 and R4 of the upper surface and the lower surface of the glass substrate 110, and may protrude in a substantially round shape from each of the first to fourth side surfaces S1, S2, S3 and S4 of the glass substrate 110 based on the second or third direction. In this case, impacts of a floor surface may be effectively prevented, and scratches due to friction during stacking may be effectively prevented. As used herein, the term “substantially round” may mean that the protrusion has an arc joining two portions of the protrusion that are the furthest from each other, and the arc may be a part of the circumference of a circle or oval. The arc may be symmetrical or asymmetrical along the longitudinal axis through a center of the glass substrate 110. The symmetry of the arc may be determined through a scanning microscope. Other methods and/or tools appreciated by one of ordinary skill in the art, even if not described in the present disclosure, may also be used. Alternatively, as in of FIG. 4C, the protection material 150 may extend to the peripheral portions R2 and R4 of each of the upper surface and the lower surface of the glass substrate 110, and may protrude in a substantially right angle form from each of the first to fourth side surfaces S1, S2, S3 and S4 of the glass substrate 110 based on the second or third direction. In this case as well, the impacts of the floor surface may be effectively prevented, and scratches due to friction during stacking may be effectively prevented. As used herein, the term “substantially right angle” may mean that the protrusion has edges that meet at an angle of 89° to 91°. The angle may be determined through a scanning microscope. Other methods and/or tools appreciated by one of ordinary skill in the art, even if not described in the present disclosure, may also be used.

The protection material 150 may include various inorganic materials and/or organic materials capable of absorbing external impact. For example, the protection material 150 may include a sealant-based material and/or a synthetic rubber-based material. The sealant-based material may include one or more of epoxy, silicone, acrylic, and/or urethane. The synthetic rubber-based material may include one or more of rubber, elastomer, and/or polyethylene. However, the present disclosure is not limited thereto, and other types of insulating materials having the functions described above may be used.

The glass substrate 110 may be a panel-unit substrate including a plurality of unit regions before singulation, and the protection material 150 may be formed on an edge surface of the panel substrate. Alternatively, the glass substrate 110 may be a unit-unit substrate after singulation, and the protection material 150 may be formed on an edge surface of each of the unit substrates.

In this manner, since the protection material 150 may be formed in various damper shapes on an edge of the glass substrate 110, cracks or breakage of the glass may be effectively prevented. For example, it may be possible to effectively prevent the generation of cracks and breakage due to micro-notches or specific impacts that may occur at an edge of the glass substrate 110 due to repeated contact, thermal shock, pressure, vibration, friction, and the like, which may occur during a process. Additionally, it may be possible to effectively prevent the generation of notches and particles that may occur when the glass substrate 110 is mounted in a cavity of the printed circuit board. Additionally, the protection material 150 may be used as a guide to improve bonding force when mounting in the cavity, and in this case, yield improvement may be expected, and design freedom may be increased by removing alignment marks, and the like, and cost reduction may be achieved.

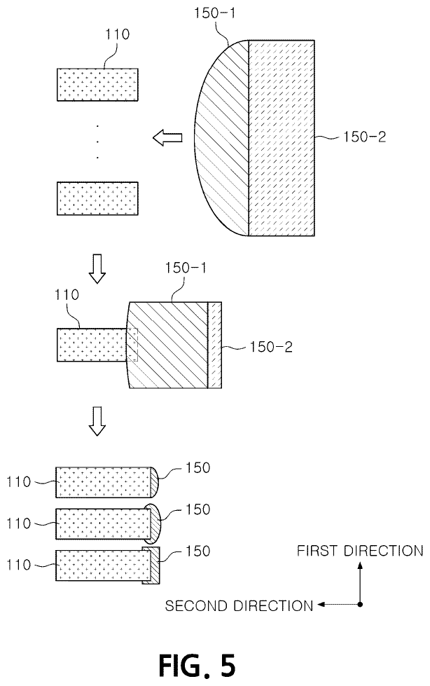

FIG. 5 is a process cross-sectional view schematically illustrating various examples of a process of forming a protection material on an edge surface of a glass substrate.

Referring to FIG. 5, first, a plurality of glass substrates 110 may be arranged. Next, a protection material 150 may be formed on an edge of each glass substrate 110. The protection material 150 may be formed by, for example, adsorbing an epoxy ink sponge 150-1 to the edge of a glass substrate 110. The epoxy ink sponge 150-1 may be formed on a substrate 150-2. However, the material of the protection material 150 is not necessarily limited to epoxy ink. Next, a damper shape of various shapes may be determined depending on the adsorption method. For example, the various shapes of the damper structure described above may be formed. Other contents may be substantially the same as described above, and therefore, redundant descriptions thereof will be omitted.

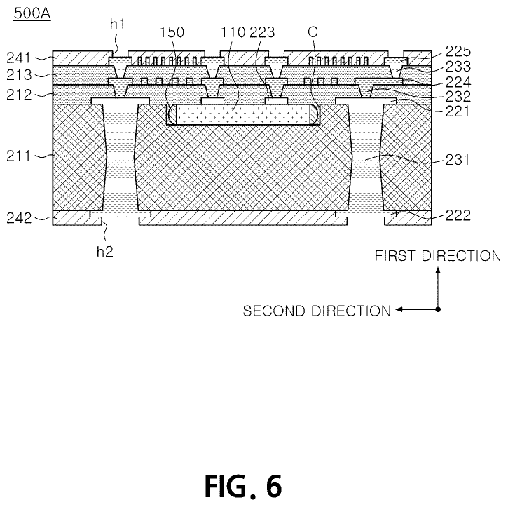

FIG. 6 is a cross-sectional view schematically showing an example of a printed circuit board.

Referring to FIG. 6, a printed circuit board 500A according to an example embodiment may include a plurality of insulating layers 211, 212 and 213, a plurality of wiring layers 221, 222, 223, 224 and 225 respectively disposed on or within the plurality of insulating layers 211, 212 and 213, a plurality of via layers 231, 232 and 233 respectively penetrating through at least one of the plurality of insulating layers 211, 212 and 213 and respectively connected to at least one of the plurality of wiring layers 221, 222, 223, 224 and 225, a glass substrate 110 at least partially disposed between the plurality of insulating layers 211, 212 and 213 in the first direction, and a protection material 150 covering side surfaces of the glass substrate 110. A structure including at least one of the plurality of insulating layers 211, 212 and 213, at least one of the plurality of wiring layers 221, 222, 223, 224 and 225, and at least one of the plurality of via layers 231, 232 and 233 may be, for example, a wiring structure. Each of the plurality of insulating layers 211, 212 and 213 may be in contact with at least a portion of a central portion of the upper surface and at least a portion of a central portion of the lower surface of a glass substrate 110. A microcircuit may be formed on the glass substrate 110. The glass substrate 110 may be embedded in the printed circuit board 500A in the form of an interposer substrate or an interconnect bridge.

The plurality of insulating layers 211, 212 and 213 may include a core insulating layer 211 and a plurality of build-up insulating layers 212 and 213 stacked on an upper surface (first surface) of the core insulating layer 211. In this case, the glass substrate 110 and the protection material 150 may be embedded in at least one of the core insulating layer 211 and the plurality of build-up insulating layers 212 and 213. For example, the core insulation layer 211 may have a cavity C penetrating through at least a portion of the core insulation layer 211 in a first direction from the upper surface of the core insulation layer 211, and the glass substrate 110 and the protection material 150 may be disposed in the cavity C, and the plurality of build-up insulation layers 212 and 213 may cover at least portions of each of the glass substrate 110 and the protection material 150, and the plurality of build-up insulation layers 212 and 213 may fill at least a portion of the cavity C.

The plurality of wiring layers 221, 222, 223, 224 and 225 may include a first core wiring layer 221 disposed on the upper surface of the core insulation layer 211, a second core wiring layer 222 disposed on the lower surface (second surface) of the core insulation layer 211, a wiring layer 223 disposed on the upper surface of the glass substrate 110, and a plurality of build-up wiring layers 224 and 225 disposed on or in the plurality of build-up insulation layers 212 and 213. If necessary, other wiring layers may be formed in the interior of the glass substrate 110 and/or on the lower surface of the glass substrate 110.

The plurality of via layers 231, 232 and 233 may include a through-via layer 231 connecting the first and second core wiring layers 221 and 222 in the core insulation layer 211, and a plurality of connection via layers 232 and 233 connecting the plurality of build-up wiring layers 224 and 225 and the wiring layer 223 and the first core wiring layer 221 in the plurality of build-up insulation layers 212 and 213. If necessary, a through-via layer connected to the wiring layer 223, or the like, may also be formed in the glass substrate 110.

A first passivation layer 241 covering the build-up wiring layer 225 disposed on an uppermost side (outermost side), among the plurality of build-up wiring layers 224 and 225 may be disposed on an upper surface of the build-up insulation layer 213 disposed on the uppermost side (outermost side), among the plurality of build-up wiring layers 224 and 225. The first passivation layer 241 may have a plurality of first openings h1 respectively exposing at least a portion of the build-up wiring layer 225 disposed on the uppermost side, among the plurality of build-up wiring layers 224 and 225. Additionally, the second passivation layer 242 covering the second core wiring layer 222 may be disposed on a lower surface of the core insulation layer 211. The second passivation layer 242 may have a plurality of second openings h2 respectively exposing at least a portion of the second core wiring layer 222.

Hereinafter, components of a printed circuit board 500A according to an example embodiment will be described in more detail with reference to the drawings.

The glass substrate 110 and the protection material 150 may be substantially the same as those described above, and therefore, redundant descriptions thereof will be omitted.

The core insulation layer 211 may include an organic insulation material. The organic insulation material may include a thermosetting resin such as an epoxy resin, a thermoplastic resin such as a polyimide, or an inorganic filler, an organic filler, and/or glass fiber (Glass Fiber, Glass Cloth or Glass Fabric) together with the resin. For example, the organic insulation material may be Copper Clad Laminate (CCL), Prepreg (PPG), or the like, but the present disclosure is not limited thereto. The core insulation layer 211 may be thicker than each of the plurality of build-up insulation layers 212 and 213. The core insulation layer 211 may be divided into a plurality of layers as needed.

Each of the plurality of build-up insulating layers 212 and 213 may include an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) together with the resin. For example, the organic insulating material may be Prepreg (PPG), Ajinomoto Build-up Film (ABF), Photoimageable Dielectric (PID), or the like, but the present disclosure is not limited thereto. The plurality of build-up insulating layers 212 and 213 may be formed of substantially the same material, but the present disclosure is not limited thereto.

Each of the first and second core wiring layers 221 and 222 and the interconnect wiring layer 223 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. Each of the first and second core wiring layers 221 and 222 and the interconnect wiring layer 223 may perform various functions according to the design. For example, the first and second core wiring layers 221 and 222 and the interconnect wiring layer 223 may include a signal pattern, a power pattern, and a ground pattern. Each of the patterns may have various shapes such as a line, a plane, and a pad. Each of the first and second core wiring layers 221 and 222 and the interconnect wiring layer 223 may include a seed layer and a plating layer. The seed layer may be formed by electroless plating (or chemical copper), and may be formed by a sputtering process if necessary. Alternatively, the seed layer may be formed using both the electroless plating and the sputtering process. The plating layer may be formed by electrolytic plating (or electrolytic copper).

Each of the plurality of build-up wiring layers 224 and 225 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. Each of the plurality of build-up wiring layers 224 and 225 may perform various functions according to the design. For example, the build-up wiring layers 224 and 225 may include a signal pattern, a power pattern, and a ground pattern. These patterns may have various shapes such as a line, a plane, and a pad. Each of the plurality of build-up wiring layers 224 and 225 may include a seed layer and a plating layer. The seed layer may be formed by electroless plating (or chemical copper), and may be formed by a sputtering process if necessary. Alternatively, the seed layer may be formed using both the electroless plating and the sputtering process. The plating layer may be formed by electrolytic plating (or electrolytic copper).

The through-via layer 231 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. The through-via layer 231 may include a plurality of through-vias penetrating between an upper surface and a lower surface of the core insulating layer 211, thereby providing an electrical connection path in the first direction within the core insulating layer 211. Each of the plurality of through-vias may perform various functions according to the design. For example, the plurality of through-vias may include a signal via, a power via, and a ground via. The through-via layer 231 may include a seed layer and a plating layer. The seed layer may be formed by electroless plating (or chemical copper), and may be formed by a sputtering process if necessary. Alternatively, the seed layer may be formed using both the electroless plating and the sputtering process. The plating layer may be formed by electrolytic plating (or electroplating).

Each of the plurality of connection via layers 232 and 233 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. Each of the plurality of connection via layers 232 and 233 may include a plurality of connection vias penetrating through at least a portion of each of the plurality of build-up insulating layers 212 and 213, thereby providing an electrical connection path in the first direction in each of the plurality of build-up insulating layers 212 and 213. Each of the plurality of connection vias may perform various functions depending on the design. For example, the connection vias may include a signal via, a power via, and a ground via. The plurality of connection vias may include filled vias in which the via holes are filled with the metal, but may also include conformal vias in which the metal is disposed along a wall surface of the via hole. Each of the plurality of connection vias may have a tapered shape in the cross-section. For example, the plurality of connection vias may have a tapered shape in which a width of an upper surface thereof is wider than a width of a lower surface thereof. The plurality of connection via layers 232 and 233 may include the same seed layer and plating layer included in the plurality of wiring layers 224 and 225, but the present disclosure is not limited thereto.

Each of the first and second passivation layers 241 and 242 may include an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) together with the resin. For example, the organic insulating material may be Ajinomoto Build-up Film (ABF), Solder Resist (SR), or the like, but the present disclosure is not limited thereto. Each of the first and second passivation layers 241 and 242 may have a plurality of first and second openings h1 and h2. A pad pattern exposed through the plurality of first and second openings h1 and h2 may be in the form of Solder Mask Defined (SMD) and/or Non Solder Mask Defined (NSMD), but the present disclosure is not limited thereto.

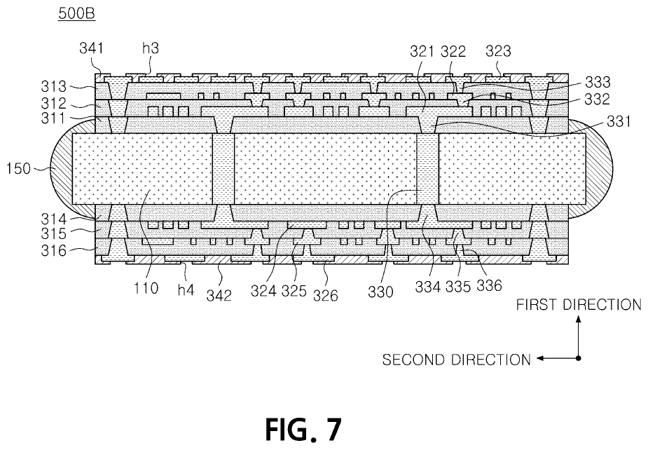

FIG. 7 is a cross-sectional diagram schematically illustrating another example of a printed circuit board.

Referring to FIG. 7, a printed circuit board 500B according to another example embodiment may include: a plurality of insulating layers 311, 312, 313, 314, 315 and 316, a plurality of wiring layers 321, 322, 323, 324, 325 and 326 respectively disposed on or within the plurality of insulating layers 311, 312, 313, 314, 315 and 316, a plurality of via layers 331, 332, 333, 334, 335 and 336 respectively penetrating through at least one of the plurality of insulating layers 311, 312, 313, 314, 315 and 316 and connected to at least one of the plurality of wiring layers 321, 322, 323, 324, 325 and 326, a glass substrate 110 at least partially disposed between a plurality of insulating layers 311, 312, 313, 314, 315 and 316 in the first direction, a protection material 150 covering side surfaces of the glass substrate 110, and a through-via layer 330 penetrating through the glass substrate 110. A structure including at least one of the plurality of insulating layers 311, 312, 313, 314, 315 and 316, at least one of the plurality of wiring layers 321, 322, 323, 324, 325 and 326, and at least one of the plurality of via layers 331, 332, 333, 334, 335 and 336 may be, for example, a wiring structure. Each of the plurality of insulating layers 311, 312, 313, 314, 315 and 316 may be in contact with at least a portion of the central portion of the upper surface and at least a portion of the central portion of the lower surface of the glass substrate 110. A microcircuit may be formed on the glass substrate 110. The glass substrate 110 may be included as a core insulating layer of a multilayer printed circuit board.

The plurality of insulating layers 311, 312, 313, 314, 315 and 316 may include a plurality of first insulating layers 311, 312 and 313 stacked on the upper surface of the glass substrate 110 and a plurality of second insulating layers 314, 315 and 316 disposed on the lower surface of the glass substrate 110. The side surfaces of the glass substrate 110 may protrude from a side surface of at least one of the plurality of first and second insulating layers 311, 312, 313, 314, 315 and 316 based on the second or third direction. The protection material 150 may extend onto the upper surface and the lower surface of the glass substrate 110 and may thus cover at least a portion of the side surface of at least one of the plurality of first and second insulating layers 311, 312, 313, 314, 315 and 316.

The plurality of wiring layers 321, 322, 323, 324, 325 and 326 may include a plurality of first wiring layers 321, 322 and 323 respectively disposed on or in a plurality of first insulating layers 311, 312 and 313 and a plurality of second wiring layers 324, 325 and 326 respectively disposed on or in a plurality of second insulating layers 314, 315 and 316. If necessary, the wiring layers may also be formed inside the glass substrate 110. Additionally, if necessary, the wiring layers may also be formed on the upper surface and/or lower surface of the glass substrate 110.

The plurality of via layers 331, 332, 333, 334, 335 and 336 may include a plurality of first via layers 331, 332 and 333 configured to connect the plurality of first wiring layers 321, 322 and 323 to each other in a plurality of first insulating layers 311, 312 and 313 and a plurality of second via layers 334, 335 and 336 configured to connect the plurality of second wiring layers 324, 325 and 326 to each other in a plurality of second insulating layers 314, 315 and 316. A through-via layer 330 configured to connect a first via layer 331 disposed on a lowermost side (innermost side), among the plurality of first via layers 331, 332 and 333, and a second via layer 334 disposed on an uppermost side, among the plurality of second via layers 334, 335 and 336, may be disposed inside the glass substrate 110.

A third passivation layer 341 covering a first wiring layer 323 disposed on an uppermost side, among the plurality of first wiring layers 321, 322 and 323, may be disposed on an upper surface of the first insulating layer 313 disposed on an uppermost side, among the plurality of first insulating layers 311, 312 and 313. The third passivation layer 341 may have a plurality of third openings h3 respectively exposing at least a portion of the first wiring layer 323 disposed on the uppermost side, among the plurality of first wiring layers 321, 322 and 323. Additionally, a fourth passivation layer 342 covering a second wiring layer 326 disposed on a lowermost side (innermost side), among the plurality of second insulating layers 314, 315 and 316, may be disposed on a lower surface of the second insulating layer 316 disposed on the lowermost side (innermost side), among the plurality of second wiring layers 324, 325 and 326. The fourth passivation layer 342 may have a plurality of fourth openings h4 respectively exposing at least a portion of the second wiring layer 326 disposed on the lowermost side, among the plurality of second wiring layers 324, 325 and 326.

Hereinafter, components of a printed circuit board 500B according to another example embodiment will be described in more detail with reference to the drawings.

The glass substrate 110 and the protection material 150 may be substantially the same as those described above, and therefore, redundant descriptions thereof will be omitted.

Each of the first and second insulating layers 311, 312, 313, 314, 315 and 316 may include an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) together with the resin. For example, the organic insulating material may be Prepreg (PPG), Ajinomoto Build-up Film (ABF), Photoimageable Dielectric (PID), or the like, but the present disclosure is not limited thereto. The plurality of first and second insulating layers 311, 312, 313, 314, 315 and 316 may be formed of substantially the same material, but the present disclosure is not limited thereto. The number of layers of the plurality of first insulating layers 311, 312 and 313 and the plurality of second insulating layers 314, 315 and 316 may be the same as each other, but the present disclosure is not limited thereto.

Each of the plurality of first and second wiring layers 321, 322, 323, 324, 325 and 326 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. The plurality of first and second wiring layers 321, 322, 323, 324, 325 and 326 may perform various functions according to the design. For example, the first and second wiring layers 321, 322, 323, 324, 325 and 326 may include a signal pattern, a power pattern, and a ground pattern. These patterns may have various shapes such as a line, a plane, and a pad. The plurality of first and second wiring layers 321, 322, 323, 324, 325 and 326 may include a seed layer and a plating layer, respectively. The seed layer may be formed by electroless plating (or chemical copper), and may be formed by a sputtering process if necessary. Alternatively, the seed layer may be formed using both the electroless plating and the sputtering process. The plating layer may be formed by electrolytic plating (or electrolytic copper).

The through-via layer 330 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. The through-via layer 330 may include a plurality of through-vias penetrating between the upper surface and the lower surface of the glass substrate 110, thereby providing an electrical connection path in the first direction in the glass substrate 110. Each of the plurality of through-vias may perform various functions depending on the design. For example, the plurality of through-vias may include a signal via, a power via, and a ground via. The through-via layer 330 may include a seed layer and a plating layer. The seed layer may be formed by electroless plating (or chemical copper), and may be formed by a sputtering process if necessary. Alternatively, the seed layer may be formed using both the electroless plating and the sputtering process. The plating layer may be formed by electrolytic plating (or electrolytic copper).

Each of the first and second via layers 331, 332, 333, 334, 335 and 336 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. The plurality of first and second via layers 331, 332, 333, 334, 335 and 336 may include a plurality of connection vias penetrating through at least a portion of each of the plurality of first and second insulating layers 311, 312, 313, 314, 315 and 316, thereby providing an electrical connection path in the first direction in each of the plurality of first and second insulating layers 311, 312, 313, 314, 315 and 316. The plurality of connection vias may perform various functions according to the design. For example, the connection vias may include a signal via, a power via, and a ground via. The plurality of connection vias may include a filled via in which a via hole is filled with the metal, but may also include a conformal via in which the metal is disposed along a wall surface of the via hole. Each of the plurality of connection vias may have a tapered shape in the cross-section. For example, the plurality of connection vias of the plurality of first via layers 331, 332 and 333 may have a tapered shape in which a width of an upper surface thereof is wider than a width of a lower surface thereof, and a plurality of connection vias of the plurality of second via layers 334, 335 and 336 may have a tapered shape in which a width of a lower surface thereof is wider than a width of an upper surface thereof. Each of the plurality of first and second via layers 331, 332, 333, 334, 335 and 336 may include the same seed layer and plating layer as those included in the plurality of first and second wiring layers 321, 322, 323, 324, 325 and 326, but the present disclosure is not limited thereto.

Each of the third and fourth passivation layers 341 and 342 may include an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) together with the resin. For example, the organic insulating material may be Ajinomoto Build-up Film (ABF), Solder Resist (SR), or the like, but the present disclosure is not limited thereto. The third and fourth passivation layers 341 and 342 may have a plurality of third and fourth openings h3 and h4, respectively. The pad patterns exposed through the plurality of third and fourth openings h3 and h4 may be in the form of Solder Mask Defined (SMD) and/or Non Solder Mask Defined (NSMD), but the present disclosure is not limited thereto.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, the expression ‘exposing’ may include not only completely exposing but also partially exposing, and exposing may mean exposing from the filling of the component. For example, exposing a pad by an opening may mean exposing the pad from a resist layer, and a surface treatment layer or the like may be further disposed on the exposed pad.

In the present disclosure, being disposing in a through-portion or a cavity may include not only a case in which an object is disposed completely in the through-portion or the cavity, but also a case in which the object protrudes upwardly or downwardly in a cross-section.

In the present disclosure, determination may be performed by including process errors, positional deviations, errors at the time of measurement, which may occur substantially in a manufacturing process. For example, a substantially round shape may include not only a completely round shape but also a roughly round shape. Additionally, a substantially right-angled shape may include not only a completely right-angled shape but also an approximately rounded shape with some corners. For example, this may be determined according to the overall shape, which is a substantially shape.

In the present disclosure, the same insulating material may denote not only a case of being the same insulating material, but also a case of including the same type of insulating material. Accordingly, the composition of the insulating material is substantially the same, but specific composition ratios thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a plurality of insulating layers;
a plurality of wiring layers respectively disposed on or within the plurality of insulating layers;
a plurality of vias, each via among the plurality of vias penetrating through at least one of the plurality of insulating layers, and each via among the plurality of vias connecting to at least one of the plurality of wiring layers;
a glass substrate having a first surface and a second surface opposing each other in a first direction, a first side surface and a second side surface opposing each other in a second direction perpendicular to the first direction, and a third side surface and a fourth side surface opposing each other in a third direction perpendicular to the first and second directions, the glass substrate is at least partially disposed between the plurality of insulating layers in the first direction; and
a protection material covering the first to fourth side surfaces of the glass substrate,
wherein each of the first surface and the second surface of the glass substrate has a peripheral portion connected to the first to fourth side surfaces and a central portion surrounded by the peripheral portion, and
the protection material is spaced apart from central portions of the first surface and the second surface of the glass substrate, respectively.

2. The printed circuit board according to claim 1,
wherein the protection material is spaced apart from peripheral portions of the first surface and the second surface of the glass substrate, and
the protection material protrudes in a substantially round shape from each of the first to fourth side surfaces of the glass substrate based on the second or third direction.

3. The printed circuit board according to claim 1,
wherein the protection material extends to the peripheral portions of the first surface and the second surface of the glass substrate, and
the protection material protrudes in a substantially round shape from each of the first to fourth side surfaces of the glass substrate based on the second or third direction.

4. The printed circuit board according to claim 1,
wherein the protection material extends to the peripheral portions of the first surface and the second surface of the glass substrate, and
the protection material protrudes in a substantially right angle shape from each of the first to fourth side surfaces of the glass substrate based on the second or third direction.

5. The printed circuit board according to claim 1,
wherein one insulating layer among the plurality of insulating layers and another insulating layer among the plurality of insulating layers are in contact with at least a portion of a central portion of the first surface and at least a portion of a central portion of the second surface of the glass substrate, respectively.

6. The printed circuit board according to claim 1,
wherein the protection material includes one or more selected from a sealant-based material and a synthetic rubber-based material,
wherein the sealant-based material includes one or more selected from epoxy, silicone, acrylic, and urethane, and
the synthetic rubber-based material includes one or more selected from rubber, elastomer, and polyethylene.

7. The printed circuit board according to claim 1,
wherein the protection material includes epoxy.

8. The printed circuit board according to claim 1,
wherein the protection material includes a synthetic rubber-based material, and
the synthetic rubber-based material includes one or more selected from rubber, elastomer, and polyethylene.

9. The printed circuit board according to claim 1, wherein the glass substrate is a panel substrate or a single unit substrate.

10. The printed circuit board according to claim 1,
wherein the plurality of insulating layers includes a core insulating layer, and a plurality of build-up insulating layers stacked on a first surface of the core insulating layer, and
the glass substrate and the protection material are embedded in at least one selected from the core insulating layer and the plurality of build-up insulating layers.

11. The printed circuit board according to claim 10,
wherein the core insulating layer has a cavity penetrating through at least a portion of the core insulating layer in the first direction from the first surface of the core insulating layer,
the glass substrate and the protection material are disposed in the cavity, and
at least one of the plurality of build-up insulating layers covers at least portions of each of the glass substrate and the protection material and fills at least a portion of the cavity.

12. The printed circuit board according to claim 11,
wherein the plurality of wiring layers include a first core wiring layer disposed on the first surface of the core insulating layer, a second core wiring layer disposed on a second surface of the core insulating layer, a wiring layer disposed on the first surface of the glass substrate, and a plurality of build-up wiring layers disposed on or in the plurality of build-up insulating layers, respectively, and
wherein the plurality of vias include a through-via connecting the first and second core wiring layers to each other in the core insulating layer, and a plurality of connection vias connecting the plurality of build-up wiring layers, the wiring layer, and the first core wiring layer to each other in the plurality of build-up insulating layers.

13. The printed circuit board according to claim 12, further comprising:
a first passivation layer disposed on a first surface of an outermost build-up insulating layer among the plurality of build-up insulating layers, the first passivation layer having a plurality of first openings respectively exposing at least a portion of an outermost build-up wiring layer among the plurality of build-up wiring layers, and
a second passivation layer disposed on the second surface of the core insulating layer, and having a plurality of second openings respectively exposing at least a portion of the second core wiring layer.

14. The printed circuit board according to claim 1,
wherein the plurality of insulating layers include a plurality of first insulating layers stacked on the first surface of the glass substrate, and a plurality of second insulating layers disposed on the second surface of the glass substrate, and
each of the first to fourth side surfaces of the glass substrate protrudes from a side surface of at least one insulating layer among the plurality of first and second insulating layers based on the second or third direction.

15. The printed circuit board according to claim 14,
wherein the protection material covers at least a portion of a side surface of at least one insulating layer among the plurality of first and second insulating layers.

16. The printed circuit board according to claim 14,
wherein the plurality of wiring layers include a plurality of first wiring layers respectively disposed on or in the plurality of first insulating layers, and a plurality of second wiring layers respectively disposed on or in the plurality of second insulating layers,
the plurality of vias include a plurality of first vias respectively connected to at least one of the plurality of first wiring layers in the plurality of first insulating layers, and a plurality of second vias respectively connected to at least one of the plurality of second wiring layers in the plurality of second insulating layers, and
a through-via penetrating through the glass substrate and respectively connected to an innermost first via among the plurality of first vias, and an innermost second via disposed among the plurality of second vias, in the glass substrate.

17. The printed circuit board according to claim 16, further comprising:
a third passivation layer disposed on a first surface of an outermost first insulating layer among the plurality of first insulating layers, the third passivation layer having a plurality of third openings respectively exposing at least a portion of an outermost first wiring layer among the plurality of first wiring layers; and
a fourth passivation layer disposed on a second surface of an outermost second insulating layer among the plurality of second insulating layers, the fourth passivation layer having a plurality of fourth openings respectively exposing at least a portion of an outermost second wiring layer among the plurality of second wiring layers.

18. A printed circuit board, comprising:
a glass substrate having a first surface and a second surface opposing each other in a first direction, a first side surface and a second side surface opposing each other in a second direction perpendicular to the first direction, and a third side surface and a fourth side surface opposing each other in a third direction perpendicular to the first and second directions;
a protection material covering the first to fourth side surfaces of the glass substrate; and
a wiring structure disposed on at least one of the first surface and the second surface of the glass substrate,
wherein each of the first surface and the second surface of the glass substrate has a peripheral portion connected to the first to fourth side surfaces and a central portion surrounded by the peripheral portion,
the protection material further covers at least a portion of the peripheral portion of the first surface of the glass substrate and at least a portion of the peripheral portion of the second surface of the glass substrate, and
the protection material is spaced apart from the central portions of each of the first surface and the second surface of the glass substrate.

19. The printed circuit board according to claim 18,
wherein the wiring structure includes one or more insulating layers, one or more wiring layers, and one or more vias.
